(19) United States
(12) Patent Application Publication
(10) Pub. No.: US 2015/0111360 A1
(43) Pub. Date: Apr. 23, 2015

(54) METHOD OF MANUFACTURING A SEMICONDUCTOR DEVICE

(71) Applicant: SAMSUNG ELECTRONICS CO., LTD., Suwon-si (KR)

(72) Inventors: Dong-Wan KIM, Hwaseong-si (KR); Byeung-Chul KIM, Suwon-si (KR); Bong-Soo KIM, Yongin-si (KR); Je-Min PARK, Suwon-si (KR); Yoo-Sang HWANG, Suwon-si (KR)

(21) Appl. No.: 14/515,874

(22) Filed: Oct. 16, 2014

(30) Foreign Application Priority Data
Oct. 17, 2013 (KR) 10-2013-0123889

(51) Int. Cl. H01L 27/108; H01L 21/3213; H01L 29/423; H01L 21/3205; H01L 49/02; H01L 21/768

(52) U.S. Cl. CPC H01L 27/10855; H01L 28/40; H01L 27/10885; H01L 27/10888; H01L 21/7685; H01L 29/4236; H01L 21/76877; H01L 21/32055; H01L 21/32133; H01L 21/32139
USPC 438/381

(57) ABSTRACT

A method of manufacturing a semiconductor device includes forming a first conductive layer on a substrate, partially removing the first conductive layer and an upper portion of the substrate to form a recess, forming a second conductive layer pattern to fill the recess, forming a third conductive layer on the second conductive layer pattern and the first conductive layer, and patterning the third conductive layer and the second conductive layer pattern to form a bit line structure and a bit line contact, respectively.

### CROSS-REFERENCE TO RELATED APPLICATION

Korean Patent Application No. 10-2013-0123889, filed on Oct. 17, 2013, in the Korean Intellectual Property Office, and entitled: “Method Of Manufacturing A Semiconductor Device,” is incorporated by reference herein in its entirety.

### BACKGROUND

Example embodiments relate to a method of manufacturing a semiconductor device. More particularly, example embodiments relate to a method of manufacturing a semiconductor device including a bit line contact and a bit line structure.

### SUMMARY

Embodiments are directed to a method of manufacturing a semiconductor device, the method including forming a first conductive layer on a substrate, partially removing the first conductive layer and an upper portion of the substrate to form a recess, forming a second conductive layer pattern to fill the recess, forming a third conductive layer on the second conductive layer pattern and the first conductive layer; and patterning the third conductive layer and the second conductive layer pattern to form a bit line structure and a bit line contact, respectively.

The third conductive layer may be formed to have a greater thickness than the first conductive layer.

The method may further include, prior to forming the bit line structure and the bit line contact, sequentially forming a barrier layer, a metal layer and a mask on the third conductive layer.

Forming the bit line structure and the bit line contact may include etching the metal layer, the barrier layer, the third conductive layer, and the second conductive layer pattern using the mask as an etching mask.

The second conductive layer pattern and the third conductive layer may be formed to include polysilicon doped with impurities. The barrier layer may be formed to include a metal nitride.

The second conductive layer pattern may include a plurality of second conductive layer patterns formed to be spaced apart from each other. The bit line contact may include a plurality of bit line contacts formed to be spaced apart from each other.

The bit line structure may be formed to extend in a first direction parallel to a top surface of the substrate.

The method may further include, prior to forming the first conductive layer, forming a first gate structure in the substrate.

Forming the first gate structure in the substrate may include forming a trench at an upper portion of the substrate, forming a first gate insulation layer on an innerwall of the trench, forming a first gate electrode on the first gate insulation layer to partially fill the trench, and forming a capping layer pattern on the first gate electrode to fill a remaining portion of the trench.

The first gate structure may be formed to extend in a second direction parallel to the top surface of the substrate and perpendicular to the first direction.

The method may further include, after forming the bit line structure and the bit line contact, forming an etch stop layer pattern on the substrate to surround the bit line structure and the bit line contact, forming an insulating interlayer on the etch stop layer pattern, partially removing the insulating interlayer and the etch stop layer pattern to form an opening exposing a top surface of the substrate, and forming a capacitor contact to fill the opening.

The method may further include, after forming the capacitor contact, forming a capacitor to contact the capacitor contact.

The substrate may include a cell region in which memory cells are formed, and a peripheral region in which peripheral circuits are formed. The method may further include, prior to forming the first conductive layer, forming a pad layer and a second gate insulation layer on the cell region and the peripheral region, respectively. The first conductive layer may be formed on the pad layer and the second gate insulation layer.

The first conductive layer may be formed to include polysilicon doped with impurities.

The method may further include, prior to forming the bit line structure and the bit line contact, forming a barrier layer, a metal layer and a mask on the third conductive layer sequentially. Forming the bit line structure and the bit line contact may include etching the metal layer, the barrier layer, the third conductive layer and the second conductive layer pattern using the mask as an etching mask to form the bit line structure and the bit line contact in the cell region. The method may further include etching the metal layer, the barrier layer, the third conductive layer, the first conductive layer and the second gate insulation layer to form the second gate structure in the peripheral region.

Embodiments are also directed to a method of manufacturing a semiconductor device including providing a substrate having a buried channel array transistor including a first gate structure formed therein, the substrate including an active region and a field region, forming a pad layer, an etch stop layer and a first conductive layer on the substrate, partially removing the pad layer, the etch stop layer, and the first conductive layer and an upper portion of the substrate to form a pad layer pattern, an etch stop layer pattern and a first conductive layer pattern and to form recesses spaced apart from each other in a first direction and a second direction, forming a second conductive layer pattern to fill the recesses, the second conductive layer pattern having a top surface substantially coplanar with a top surface of the first conductive pattern, forming a third conductive layer, a barrier layer, a metal layer, and a mask on the second conductive layer pattern and the first conductive layer pattern, and patterning the metal layer, the barrier layer and the third conductive layer using the mask to form a metal layer pattern, a barrier layer pattern, and a third conductive layer pattern constituting bit line structures and further patterning the second conductive layer pattern to form bit line contacts in the recesses, the bit line contacts contacting the substrate in the active region.

The second conductive layer pattern and the third conductive layer pattern may be formed of a same conductive material such that the third conductive layer pattern merges with the bit line contact.

The second conductive layer pattern and the third conductive layer pattern may each include polysilicon doped with impurities.

The bit line structures may extend in the first direction parallel to the substrate.

The method may further include forming a capacitor contact between two of the bit line structures and forming a capacitor electrically connected to the capacitor contact.

### BRIEF DESCRIPTION OF THE DRAWINGS

Features will become apparent to those of skill in the art by describing in detail exemplary embodiments with reference to the attached drawings in which:

FIGS. 1 and 3 illustrate plan views depicting stages of a method of manufacturing a semiconductor device in accordance with example embodiments; and

FIG. 2 and FIGS. 4 to 15 illustrate cross-sectional views depicting stages of the method of manufacturing the semiconductor device in accordance with example embodiments.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will be understood that when an element or layer is referred to as being “on,” or “connected to” another element or layer, it can be directly on or connected to the other element or layer or intervening elements or layers may be present. Like numerals refer to like elements throughout. As used herein, the term “and/or” includes any and all combinations of one or more of the associated listed items.

Spatially relative terms, such as “beneath,” “lower,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “beneath” other elements or features would then be oriented “above” the other elements or features. Thus, the exemplary term “beneath” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope thereof.

Unless otherwise defined, all terms (including technical and scientific terms) used herein have the same meaning as commonly understood by one of ordinary skill in the pertinent art. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Although corresponding plan views and/or perspective views of some cross-sectional view(s) may not be shown, the cross-sectional view(s) of device structures illustrated herein provide support for a plurality of device structures that extend along two different directions as would be illustrated in a plan view, and/or in three different directions as would be illustrated in a perspective view. The two different directions may or may not be orthogonal to each other. The three different directions may include a third direction that may be orthogonal to the two different directions. The plurality of device structures may be integrated in a same electronic device. For example, when a device structure (e.g., a memory cell structure or a transistor structure) is illustrated in a cross-sectional view, an electronic device may include a plurality of the device structures (e.g., memory cell structures or transistor structures), as would be illustrated by a plan view of the electronic device. The plurality of device structures may be arranged in an array and/or in a two-dimensional pattern.

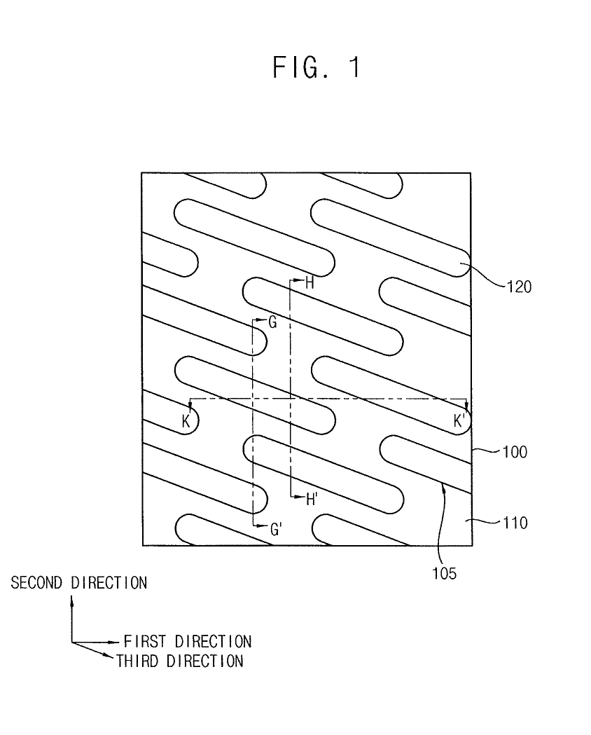

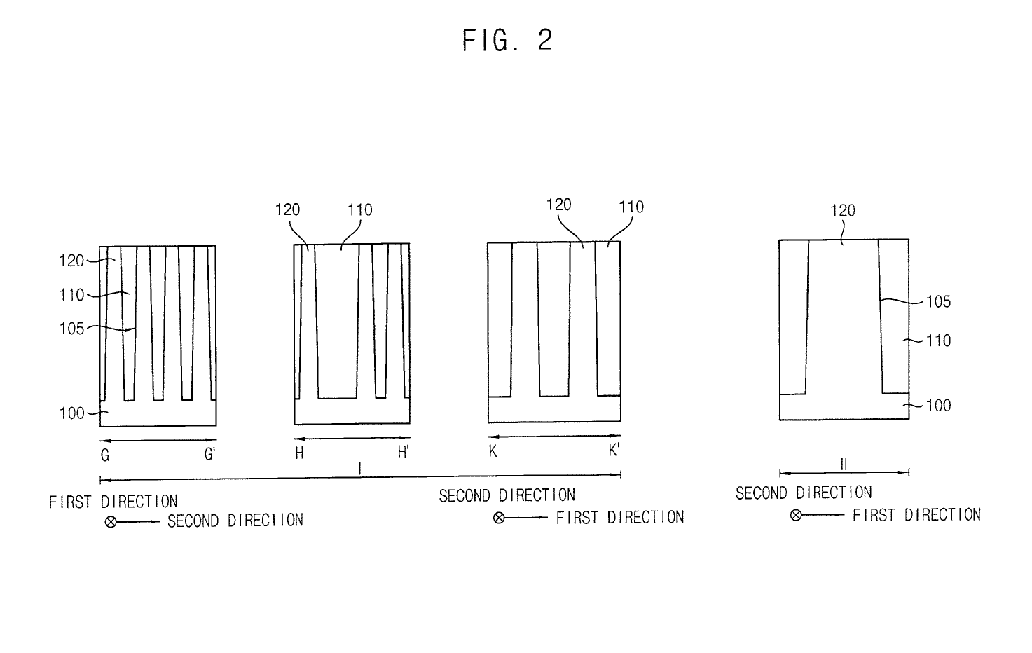

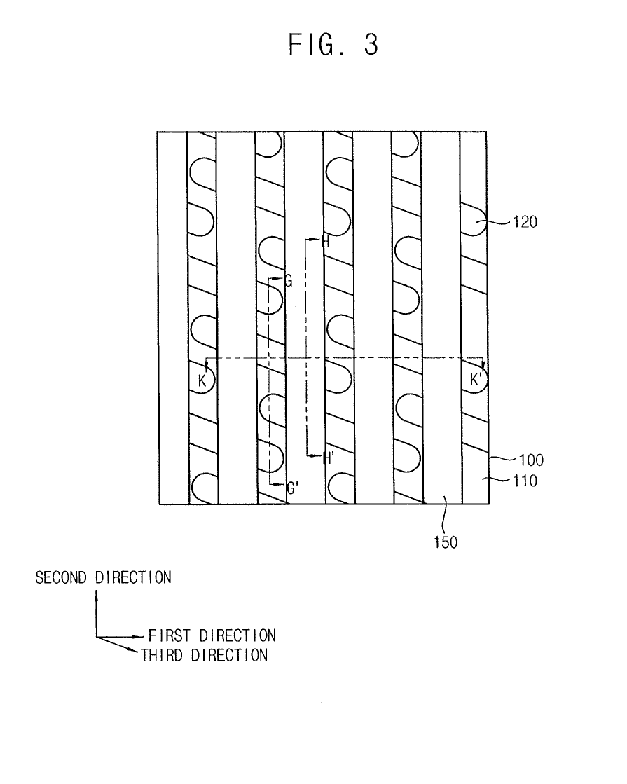

FIGS. 1 and 3 illustrate plan views depicting stages of a method of manufacturing a semiconductor device in accordance with example embodiments, and FIG. 2 and FIGS. 4 to 15 illustrate cross-sectional views depicting stages of the method of manufacturing the semiconductor device in accordance with example embodiments. Each of the cross-sectional views includes first and second regions I and II as a cell region and a peripheral region of a substrate, respectively. Cross-sectional views respectively cut along a line G-G′, a line H-H′ and a line K-K′ of the substrate are illustrated in the first region I. The line G-G′ and the line H-H′ extend in a second direction substantially parallel to a top surface of the substrate, and the line K-K′ extends in a first direction substantially parallel to the top surface of the substrate and substantially perpendicular to the second direction. A cross-sectional view cut along the first direction of the substrate is illustrated in the second region II. Each of the plan views illustrates only the first region I of the substrate.

Referring to FIGS. 1 and 2, an upper portion of a substrate 100 may be removed by an etching process using an etching mask (not shown) formed on the substrate 100 in the first and second regions I and II to form a first trench 105 in the first and second regions I and II. The substrate 100 may be a silicon substrate, a germanium substrate, a silicon-germanium substrate, a silicon-on-insulator (SOI) substrate, a germanium-on-insulator (GOI) substrate, etc. The etching mask may be formed to include a nitride, e.g., silicon nitride.

Thereafter, an isolation layer pattern 110 may be formed in the first trench 105. The isolation layer pattern 110 may be formed by forming an isolation layer on the substrate 100 to sufficiently fill the first trench 105, and planarizing an upper portion of the isolation layer until a top surface of the substrate 100 is exposed. The isolation layer may be formed to include an oxide, e.g., silicon oxide.

A portion of the substrate 100 on which the isolation layer pattern 110 is formed may be defined as a field region, and a portion of the substrate 100 on which the isolation layer pattern 110 is not formed may be defined as an active region 120. In example embodiments, a plurality of active regions 120 may be formed to have an isolated shape, each of which may extend in a third direction that is neither parallel nor perpendicular to either the first direction or the second direction but that is substantially parallel to the top surface of the substrate 100.

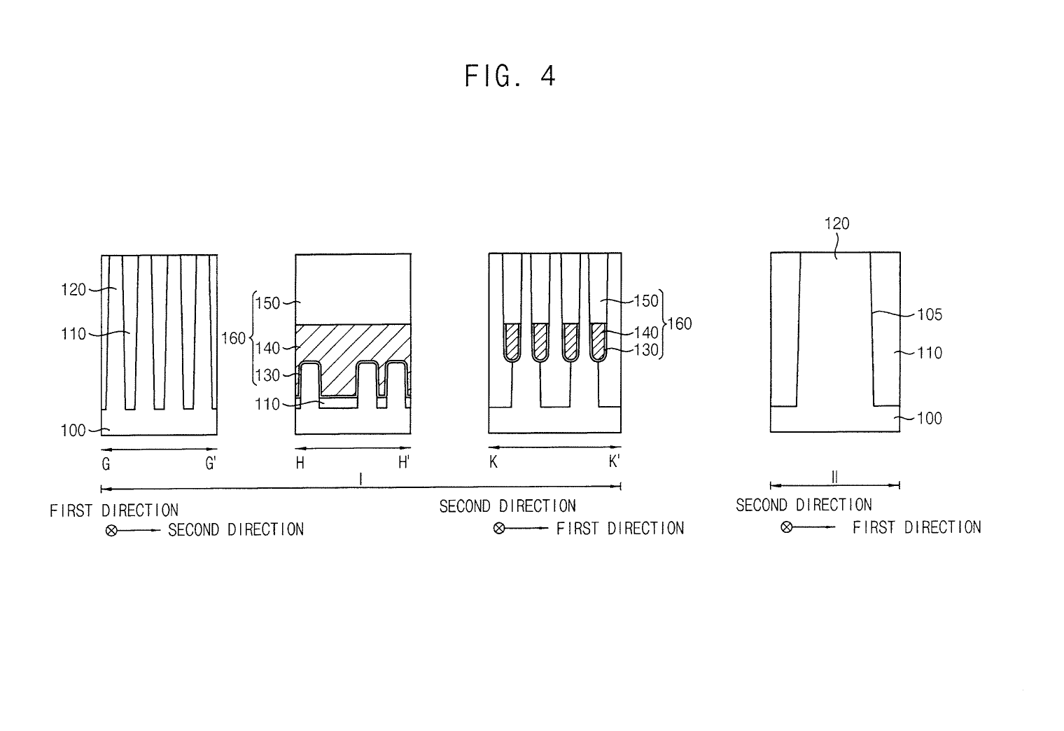

An upper portion of the substrate 100 may be doped with impurities to form a first impurity region in the first region I. The first impurity region together with a first gate structure 160 (refer to FIG. 4) sequentially formed may be defined as a first transistor, and the first impurity region may serve as source/drain regions of the first transistor.

Referring to FIGS. 3 and 4, the substrate 100 and the isolation layer pattern 110 may be partially removed in the first region I to form second trenches, each of which may extend in the second direction. The second trenches may be formed to have different depths at the substrate 100 and the isolation layer pattern 110 according to the etching selectivity therebetween. In example embodiments, two second trenches may be formed in each active region 120 of the substrate 100.

Thereafter, the first gate structure 160 may be formed in each of the second trenches. The first gate structure 160 may be formed to include a first gate insulation layer 130, a first gate electrode 140 and a capping layer pattern 150. The first gate insulation layer 130 may be formed on a lower inner wall of each second trench, the first gate electrode 140 may be formed on the first gate insulation layer 130 to fill a lower portion of each second trench, and the capping layer pattern 150 may be formed on the first gate electrode 140 to fill an upper portion of each second trench. A plurality of gate structures 160 may be formed in the first direction, each of which may be formed in the first region I to extend in the second direction.

In example embodiments, the first gate insulation layer 130 may be formed on an inner wall of the second trench by a thermal oxidation process or a chemical vapor deposition (CVD) process, and thus may be formed to include an oxide, e.g., silicon oxide.

The first gate electrode 140 may be formed by forming a first gate electrode layer on the first gate insulation layer 130, the isolation layer pattern 110 and the substrate 100 to sufficiently fill the second trenches, and removing an upper portion of the first gate electrode layer by a chemical mechanical polishing (CMP) process and/or an etch back process. Accordingly, the first gate electrode 140 may be formed in a lower portion of each second trench, and an upper portion of the first gate insulation layer 130 may be removed simultaneously, such that the first gate insulation layer 130 is formed on the lower inner wall of each second trench. The first gate electrode layer may be formed to include, a metal, e.g., tungsten (W), titanium (Ti), tantalum (Ta), etc., or a metal nitride, e.g., tungsten nitride (WN), titanium nitride (TiN), tantalum nitride (TaN), etc.

The capping layer pattern 150 may be formed by forming a capping layer on the first gate electrode 140, the first gate insulation layer 130, the isolation layer pattern 110 and the substrate 100 to sufficiently fill remaining portions of the second trenches, and planarizing an upper portion of the capping layer until a top surface of the isolation layer pattern 110 is exposed. Accordingly, the capping layer pattern 150 may be formed in an upper portion of each second trench. The capping layer may be formed to include a nitride, e.g., silicon nitride.

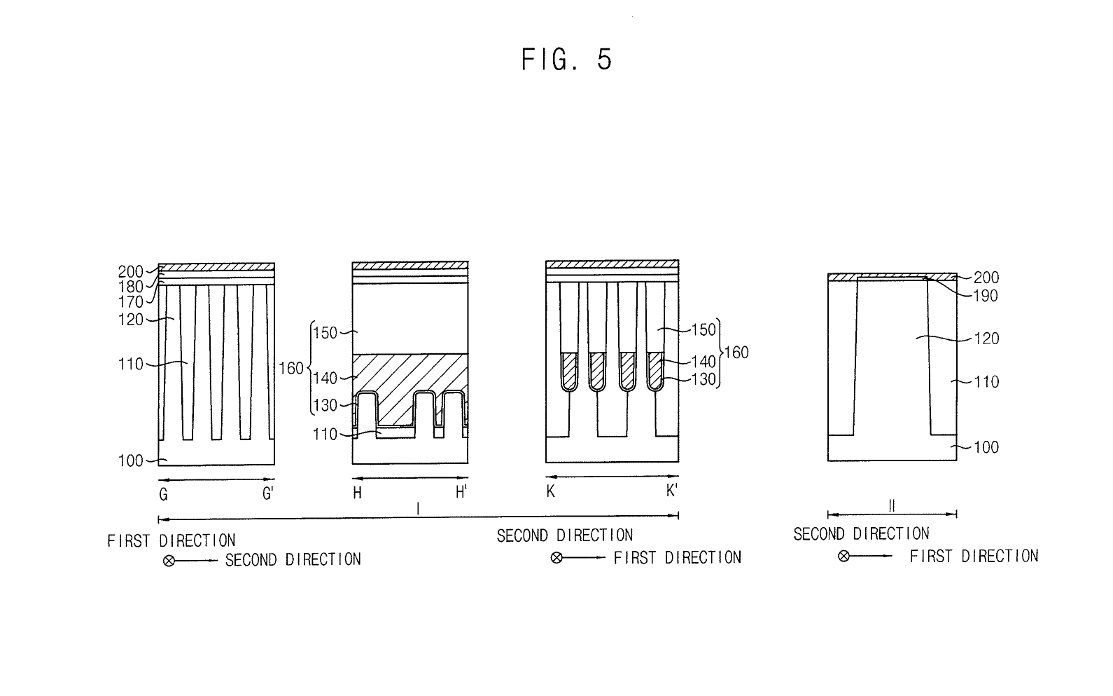

Referring to FIG. 5, a second gate insulation layer 190 may be formed on the substrate 100 in the second region II. A pad layer 170 and a first etch stop layer 180 may be sequentially formed on the substrate 100, the isolation layer pattern 110, and the capping layer pattern 150 in the first region I. A first conductive layer 200 may be formed on the first etch stop layer 180 in the first region I, and on the isolation layer pattern 110 and the second gate insulation layer 190 in the second region II.

In example embodiments, the second gate insulation layer 190 may be formed on an exposed top surface of the substrate 100 in the second region II by a thermal oxidation process, and thus may be formed to include an oxide, e.g., silicon oxide.

The pad layer 170 may be formed to include an oxide, e.g., silicon oxide. The first etch stop layer 180 may be formed to include a nitride, e.g., silicon nitride. The pad layer 170 and the first etch stop layer 180 may be formed to have an etch selectivity with respect to each other.

The first conductive layer 200 may be formed to include, e.g., polysilicon doped with impurities. In one example embodiment, the first conductive layer 200 may be formed to have a thickness of about 60 Å.

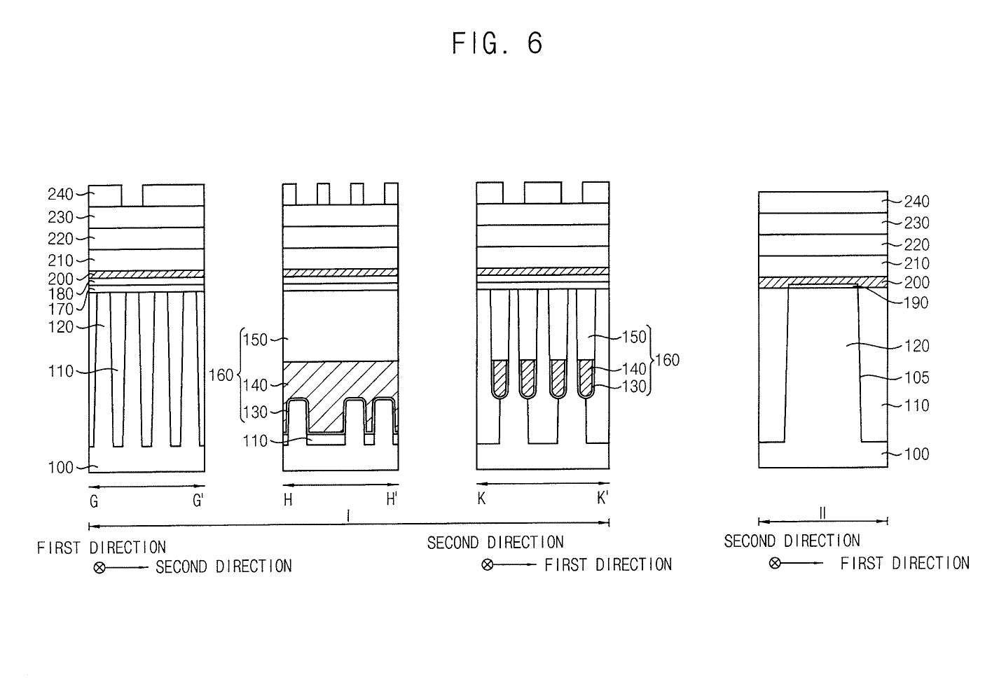

Referring to FIG. 6, first to third mask layers 210, 220, and 230 and a photoresist pattern 240 may be sequentially formed on the first conductive layer 200. The photoresist pattern 240 may be formed to expose a portion of a top surface of the third mask layer 230 formed in the first region I.

The first mask layer 210 may be formed to include an oxide, e.g. silicon oxide. The second mask layer 220 may be formed to include, e.g., an amorphous carbon layer (ACL). The third mask layer 230 may be formed to include, e.g., silicon oxynitride.

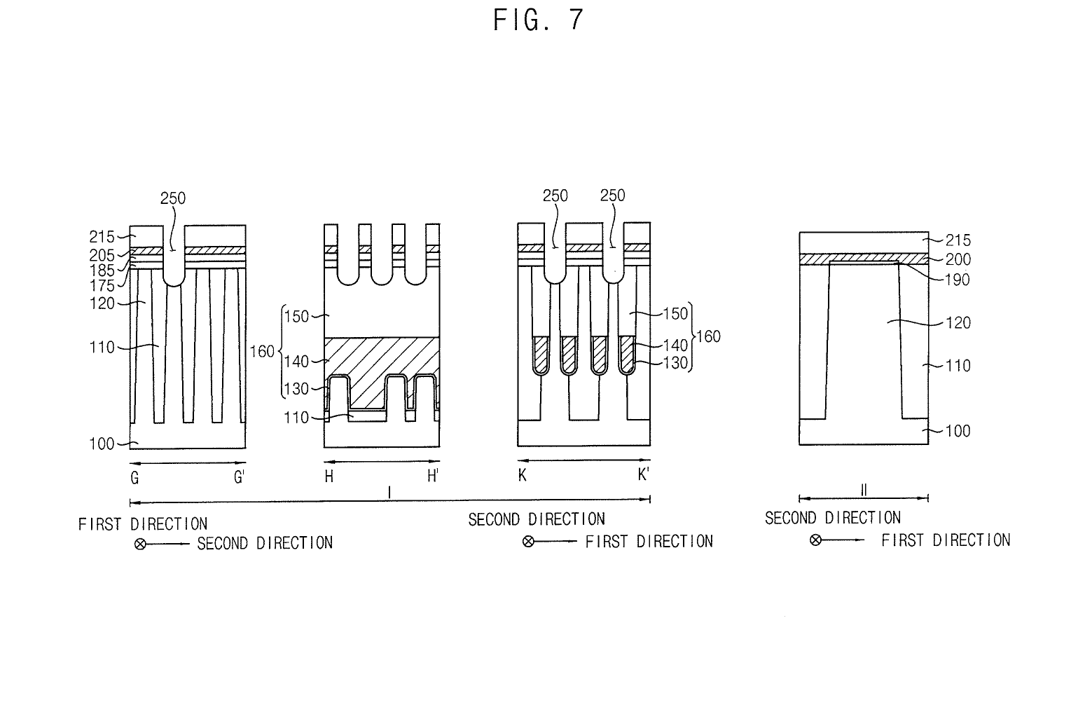

Referring to FIG. 7, the first to third mask layers 210, 220, and 230 may be sequentially patterned using the photoresist pattern 240 as an etching mask such that a first mask 215 is formed. The first conductive layer 200, the etch stop layer 180, the pad layer 170 and an upper portion of the substrate 100 may be partially removed using the first mask 215 as an etching mask to form recesses 250 in the first region I. The recesses 250 may be formed to be spaced apart each other in both of the first and second directions. Each of the recesses 250 may expose a portion of a top surface of the active region 120.

Accordingly, a pad layer pattern 175, a first etch stop layer pattern 185, and a first conductive layer pattern 205 may be formed in the first region I The capping layer pattern 150 and the isolation layer pattern 110 may be partially removed when the recesses 250 are formed.

The second gate insulation layer 190 and the first conductive layer 200 may remain beneath the first mask 215 in the second region II.

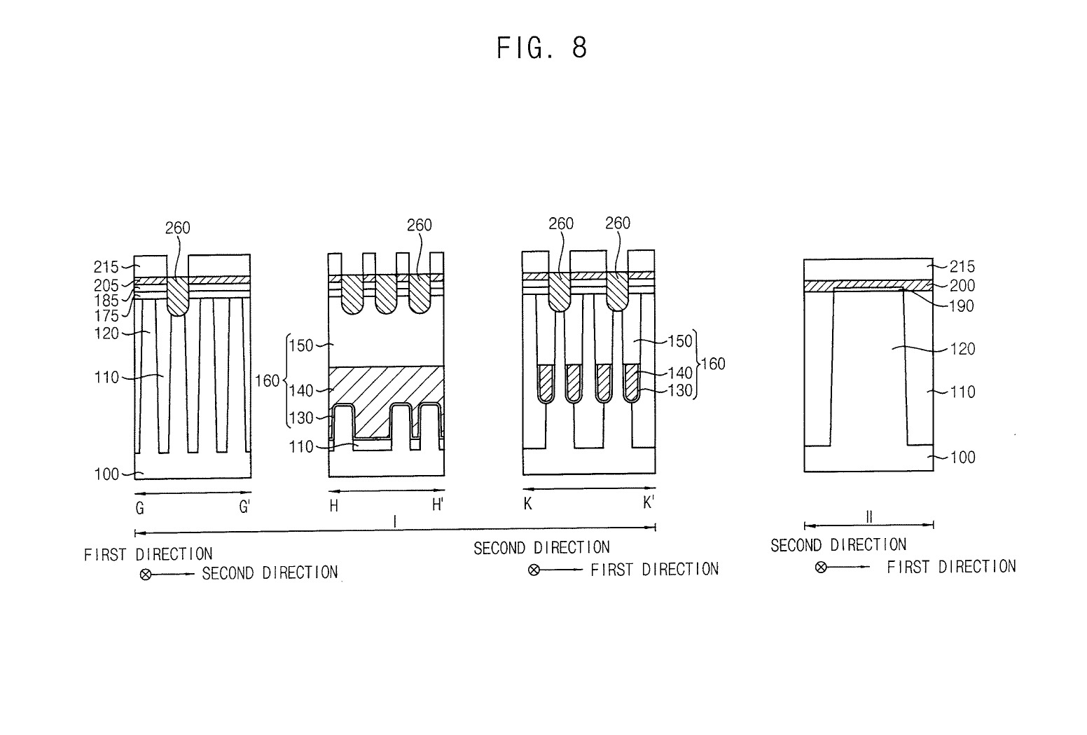

Referring to FIG. 8, a second conductive layer pattern 260 may be formed to fill each of the recesses 250.

In example embodiments, the second conductive layer pattern 260 may be formed by forming a second conductive layer on the substrate 100, the capping layer pattern 150, the isolation layer pattern 110, and the first mask 215 in the first region I to sufficiently fill the recesses 250, and removing an upper portion of the second conductive layer by a CMP process and/or an etch back process. The second conductive layer pattern 260 may be formed to have a top surface substantially coplanar with a top surface of the first conductive layer pattern 205.

A plurality of second conductive layer patterns 260 may be formed to be spaced apart from each other in both of the first and second directions. The second conductive layer may be formed to include, e.g., polysilicon doped with impurities.

Thereafter, the first mask 215 may be removed, and a cleaning process may be performed on the substrate 100.

The first mask 215 may be removed by, e.g., a wet etching process. In example embodiments, the cleaning process may be performed by a strip process and/or a plasma native-oxide cleaning (PNC) process. The cleaning process may be performed such that a native oxide layer does not remain on the first and second conductive layer patterns 205 and 260.

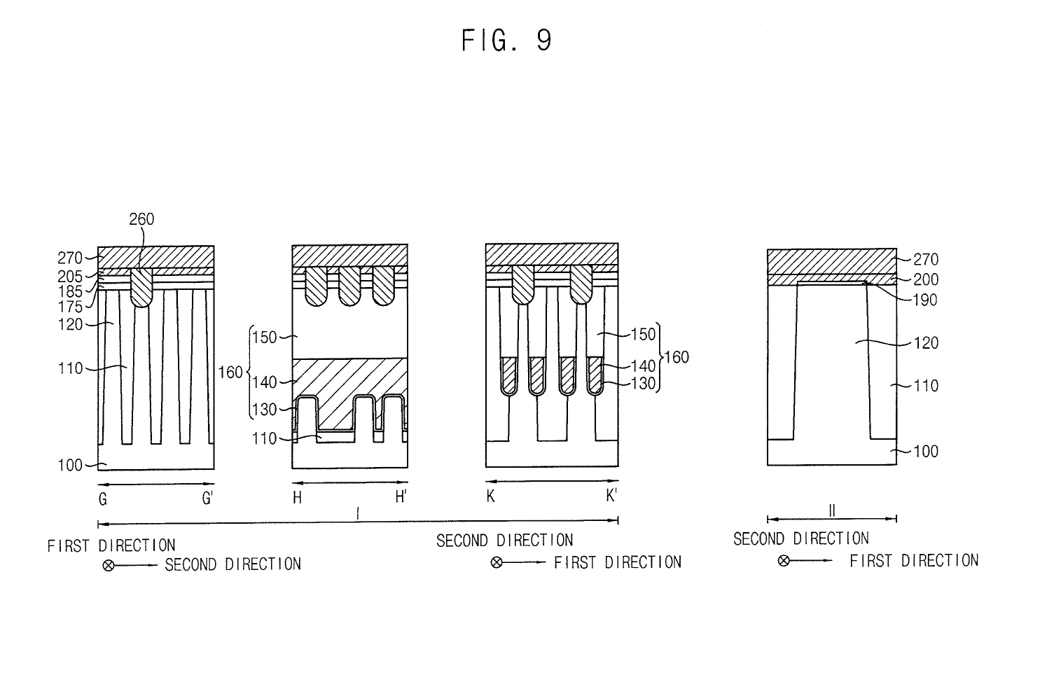

Referring to FIG. 9, a third conductive layer 270 may be formed on the first and second conductive layer patterns 205 and 260 in the first region I and on the first conductive layer 200 in the second region II. A top surface of the second conductive layer pattern 260 may be covered by the third conductive layer 270.

In example embodiments, the third conductive layer 270 may be formed to include a material substantially the same as the material of the first and second conductive layer patterns 205 and 260. For example, the third conductive layer 270 may be formed to include polysilicon doped with impurities. The third conductive material may be merged with the first and second conductive layer patterns 205 and 260. The third conductive layer 270 may be formed to have a greater thickness thicker than t the first conductive layer pattern 250. In one example embodiment, the third conductive layer 270 may be formed to have a thickness of about 300 Å.

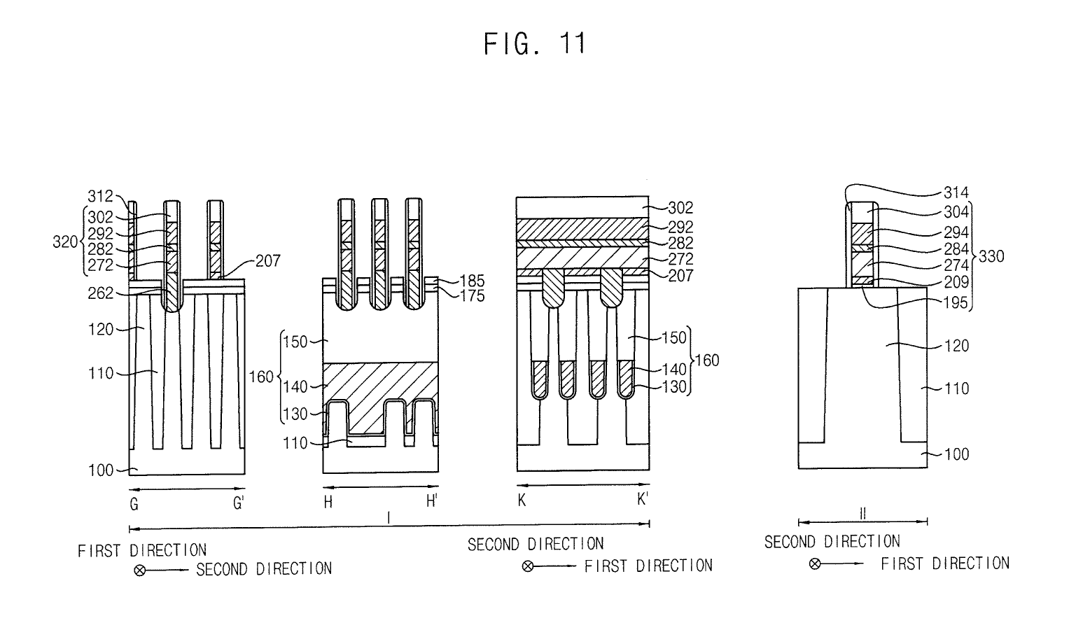

As described above, the third conductive layer 270 may be formed on the second conductive layer pattern 260 in the first region I. A third conductive layer pattern 272 (refer to FIG. 11) may be formed on a bit line contact 262 (refer to FIG. 11) sequentially formed. In this case, the third conductive layer pattern 272 may be formed to have a greater thickness than the first conductive layer pattern 205. An aspect ratio of the recess 250 may be minimized. Therefore, even though a sidewall of the recess 250 may have a high slope, no void may be formed in the second conductive layer pattern 260. As a result, etching defects may not be generated during a patterning process for formation of the bit line contact 262 and a bit line structure 320 (refer to FIG. 11). Thus, misalignment of the bit line contact 262 and the bit line structure 320 may be prevented.

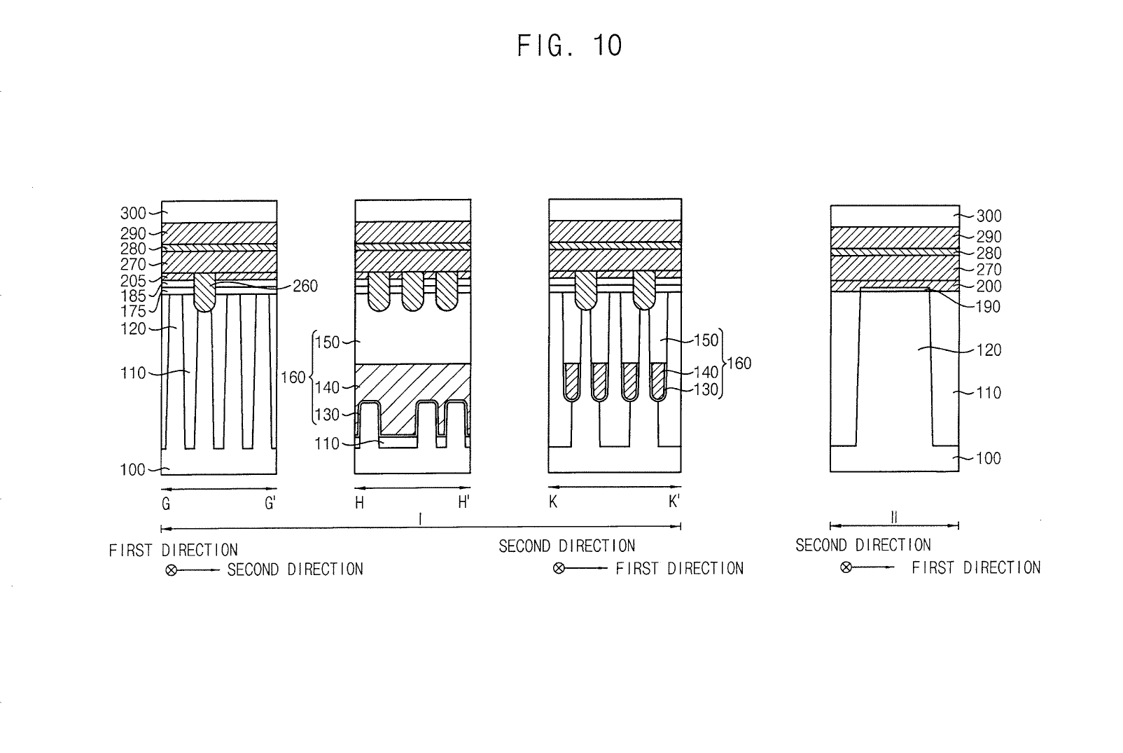

Moreover, even if a void were to be formed in the second conductive layer pattern 260 in the recess 250, the third conductive layer pattern 272 may cover and/or fill the void. Thus, an additional process for filling and/or removing the void need not performed before a barrier layer 280 (refer to FIG. 10) is formed for formation of the bit line structure 320. Introduction of a material of the barrier layer 280 into the void may be prevented.

Accordingly, a deterioration of the electrical characteristics of the semiconductor device due to a void may be prevented.

Referring to FIG. 10, the barrier layer 280, a metal layer 290, and a fourth mask layer 300 may be sequentially formed on the third conductive layer 270 in both of the first and second regions I and II.

The barrier layer 280 may be formed to include a metal, e.g., titanium (Ti), tantalum (Ta), etc., and/or a metal nitride, e.g., titanium nitride (TiN), tantalum nitride (TaN), etc.

The metal layer 290 may be formed to include a material having a lower resistance than the first and second conductive layer patterns 205 and 260, and the third conductive layer 270, e.g., tungsten (W), etc.

The fourth mask layer 300 may be formed to include, e.g., silicon nitride.

Referring to FIG. 11, the fourth mask layer 300 may be etched to form fourth and fifth masks 302 and 304 in the first and second regions I and II, respectively. The metal layer 290, the barrier layer 280, the third conductive layer 270, and the first and second conductive layer patterns 205 and 260 may be sequentially patterned in the first and second regions I and II using the fourth and fifth masks 302 and 304 as an etching mask, respectively. Accordingly, the bit line structure 320 including the third conductive layer pattern 272, a first barrier layer pattern 282, a first metal layer pattern 292, and a fourth mask 302 sequentially stacked, with the bit line contact 262 therebeneath, may be formed in the first region I. A second gate structure 330 including a second gate insulation layer pattern 195, fourth and fifth conductive layer patterns 209 and 274, a second barrier layer pattern 284, a second metal layer pattern 294, and the fifth mask 304 sequentially stacked may be formed in the second region II.

Due to the patterning process, a portion of a top surface of the first etch stop layer pattern 185 may be exposed in the first region I, and portions of the top surfaces of the substrate 100 and the isolation layer pattern 110 may be exposed in the second regions II. In example embodiments, the third conductive layer 270 may be formed to include a material substantially the same as the materials of the first and second conductive layer patterns 205 and 260. Thus, the bit line contact 262 and the third conductive layer pattern 272 may be merged in the first region I, and the fourth and fifth conductive layer patterns 209 and 274 may be merged in the second region II.

A plurality of bit line contacts 262 may be formed in both of the first and second directions to have an isolated shape and to fill a portion of each recess 250. A plurality of bit line structures 320 may be formed in the second direction. Each of the bit line structures 320 may be formed to extend in the first direction. The second gate structure 330 may be formed to extend in the second direction.

Thereafter, a first spacer 312 may be formed on sidewalls of the bit line contact 262 and the bit line structure 320 in the first region I, and a second spacer 314 may be formed on a sidewall of the second gate structure 330 in the second region II.

In example embodiments, the first and second spacers 312 and 314 may be formed by forming a first spacer layer covering the bit line contact 262 and the bit line structure 320 in the first region I and a second spacer layer covering the second gate structure 330 in the second region II, and etching the first and second spacer layers anisotropically. Accordingly, a plurality of first spacers 312 may be formed in the second direction, each of which may be formed to extend in the first direction, and a second spacer 314 may be formed to extend in the second direction. The first and second spacer layers may be formed to include an insulating material, e.g., silicon oxide, silicon nitride, etc.

After forming a second spacer 314, an ion implantation process may be performed on the substrate 100 in the second region II to form a second impurity region at an upper portion of the substrate 100 adjacent to the second gate structure 330. Accordingly, the second gate structure 330 and the second impurity region may be defined as a second transistor.

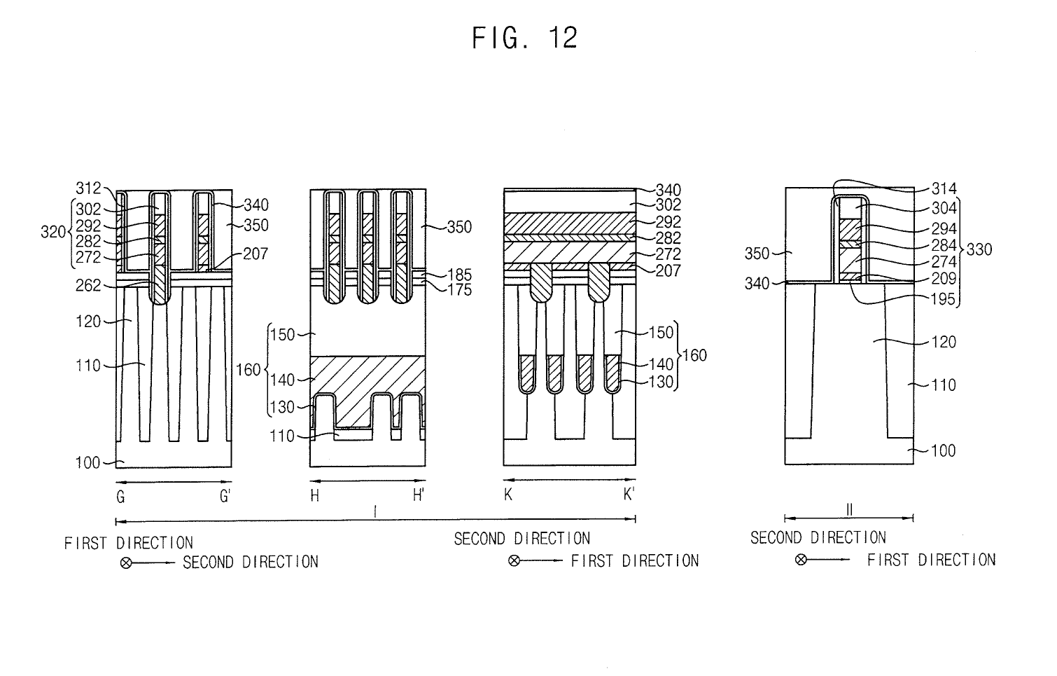

Referring to FIG. 12, a second etch stop layer 340 may be formed on the first etch stop layer pattern 185, the first spacers 312, and the fourth masks 302 in the first region I to surround the bit line contact 262 and the bit line structure 320. The second etch stop layer 340 may also be formed on the substrate 100, the second spacer 314, and the fifth mask 304 in the second region II to surround the second gate structure 330. The second etch stop layer 340 may be further formed on an upper sidewall of the recess 250 that is exposed by removing a portion of the second conductive layer pattern 260 during formation of the bit line contact 262. Accordingly, the second etch stop layer 340 may be formed to fill a remaining portion of the recess 250. The second etch stop layer 340 may be formed to include, e.g., silicon nitride.

Thereafter, a first insulating interlayer may be formed on the second etch stop layer 340 in the first and second regions I and II to cover the bit line structure 320 and the gate structure 330. The first insulating interlayer may be planarized until a top surface of the second etch stop layer 340 is exposed to form a first insulating interlayer pattern 350 in the first and second regions I and II. Accordingly, a plurality of first insulating interlayer patterns 350 may be formed in the second direction. Each of the first insulating interlayer patterns 350 may be formed between two bit line structures 320 adjacent to each other amd may extend in the first direction. The first insulating interlayer pattern 350 may cover the second gate structure 330 in the second region II. The first insulating interlayer may be formed to include an oxide, e.g., silicon oxide.

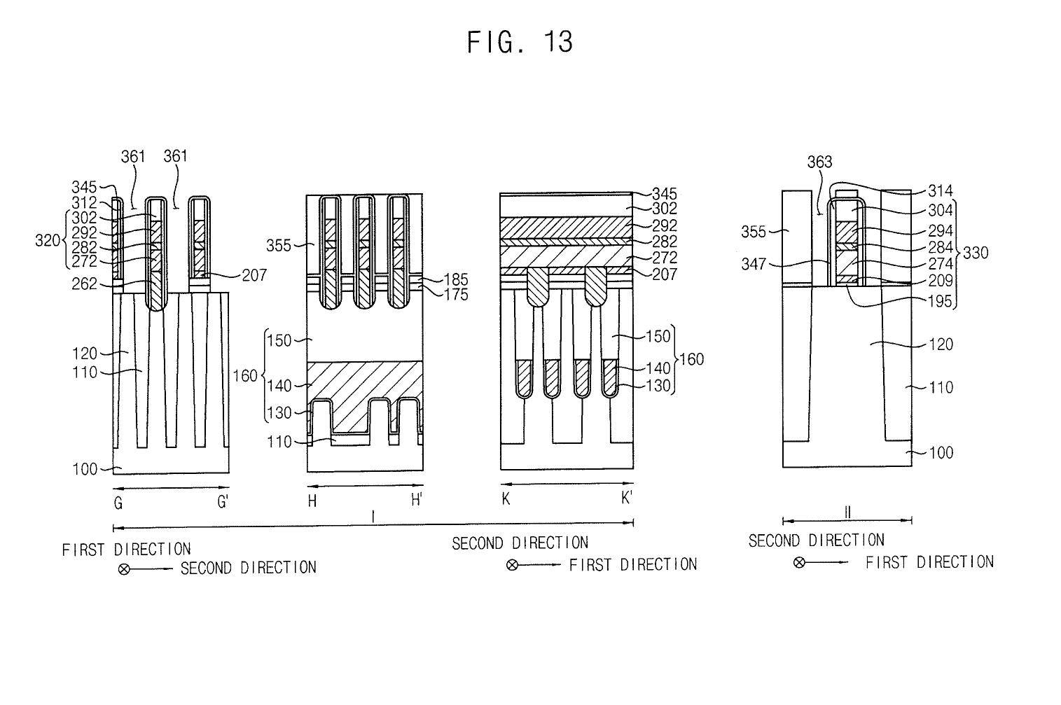

Referring to FIG. 13, the first insulating interlayer pattern 350, the second etch stop layer 340, the first etch stop layer pattern 185, and the pad layer pattern 175 may be partially removed in the first region I. The first insulating interlayer pattern 350 and the second etch stop layer 340 may be partially removed in the second region II. Thus, first and second openings 361 and 363 exposing portions of the top surface of each active region 120 in the first and second regions I and II, respectively, may be formed. The first and second openings 361 and 363 may expose portions of top surfaces of the first and second impurity regions formed at the upper portions of the substrate 100, respectively.

In example embodiments, a plurality of first openings 361 may be formed in the first direction. Each of the first openings 361may be formed between two bit line structures 320 adjacent to each other. Each of the first openings 361 may be formed to be self-aligned with the bit line structure 320 and the bit line contact 262. Two first openings 361 may be formed in each active region 120 in the first region I.

In example embodiments, a plurality of second openings 363 may be formed in the first direction.

According to the etching process, the second etch stop layer 340 may be converted into second and third etch stop layer patterns 345 and 347 in the first and second regions I and II, respectively. A plurality of second etch stop layer patterns 345 may be formed in the second direction. Each of the second etch stop layer patterns 345 may be formed to surround one the bit line structures 320 in the first region I and may extend in the first direction. The third etch stop layer pattern 347 may be formed to surround the second gate structure 330 in the second region II and may extend in the first direction.

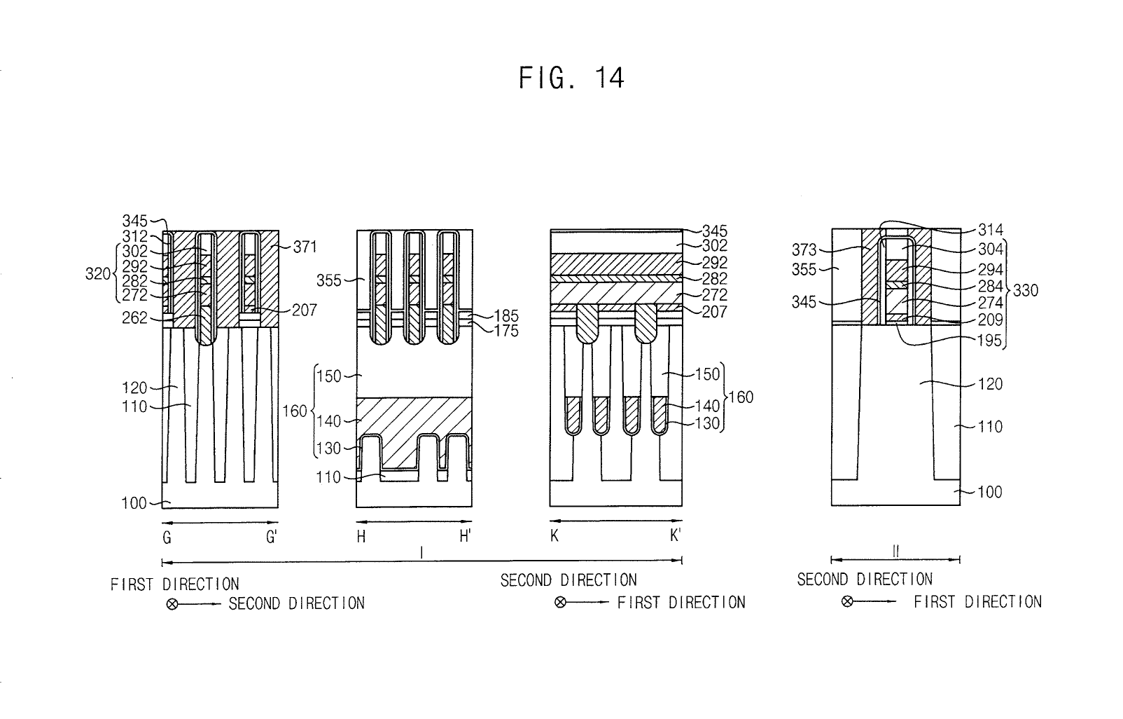

Referring to FIG. 14, a capacitor contact 371 filling the first opening 361, and a contact plug 373 filling the second opening 363 may be formed in the first and second regions I and II, respectively.

The capacitor contact 371 may be formed by forming a seventh conductive layer on the substrate 100, the second etch stop layer pattern 345, and the first insulating interlayer pattern 355 in the first region I to sufficiently fill the first openings 361, and planarizing an upper portion of the seventh conductive layer until a top surface of the second etch stop layer pattern 345 is exposed. The capacitor contact 371 may be formed on the active region 120 in the first region I to contact the top surface of the first impurity region.

The contact plug 373 may be formed by forming a eighth conductive layer on the substrate 100, the first insulating interlayer pattern 355, and the third etch stop layer pattern 347 in the second region II to sufficiently fill the second opening 363, and planarizing an upper portion of the eighth conductive layer until a top surface of the third conductive layer pattern 347 is exposed. Accordingly, the contact plug 373 may be formed on the active region 120 in the second region II to contact the top surface of the second impurity region.

The seventh and eighth conductive layers may be formed to include a metal, e.g., tungsten (W), aluminum (Al), copper (Cu), etc., and/or polysilicon doped with impurities.

In other implementations, the capacitor contact 371 and the contact plug 373 may be formed simultaneously. For example, a ninth conductive layer may be formed in the first and second regions I and II to fill the first and second openings 361 and 363, respectively, and an upper portion of the ninth conductive layer may be planarized to form the capacitor contact 371 and the contact plug 373.

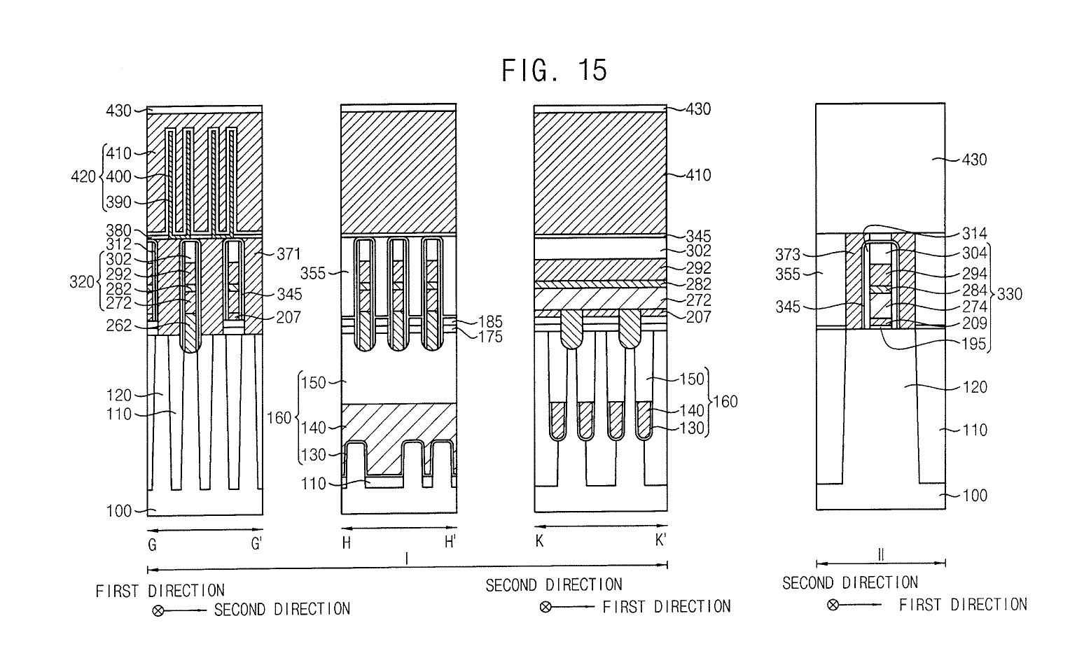

Referring to FIG. 15, a capacitor 420 may be formed in the first region I to contact a top surface of the capacitor contact 371.

A fourth etch stop layer 380 and a mold layer may be sequentially formed on the second etch stop layer pattern 345 and the capacitor contact 371 in the first region I. The fourth etch stop layer 380 and the mold layer may be removed partially to form contact holes exposing top surfaces of the capacitor contacts 371. A top surface of the second etch stop layer pattern 345 may be also exposed by the holes.

A lower electrode layer may be formed on sidewalls of the contact holes, the exposed top surfaces of the capacitor contacts 371, and the mold layer. A sacrificial layer may be formed on the lower electrode layer to sufficiently fill remaining portions of the contact holes, and upper portions of the lower electrode layer and the sacrificial layer may be planarized until a top surface of the mold layer is exposed to divide the lower electrode layer into a plurality of pieces. Remaining portions of the sacrificial layer and the mold layer may be removed by, e.g., a wet etching process, and thus, a cylindrical lower electrode 390 may be formed on the exposed top surface of the capacitor contact 371. In other implementations, a pillar lower electrode 390 may be formed to sufficiently fill each of the contact holes.

Thereafter, a dielectric layer 400 may be formed on the lower electrode 390 and the fourth etch stop layer 380, and an upper electrode 410 may be formed on the dielectric layer 400 to form the capacitors 420 each of which may include the lower electrode 390, the dielectric layer 400, and the upper electrode 410.

In example embodiments, the lower electrode 390 may be formed to include a material substantially the same as that of the upper electrode 410, e.g., polysilicon doped with impurities. The dielectric layer 400 may be formed to include an oxide, e.g., silicon oxide, a metal oxide, etc., and/or a nitride, e.g., silicon nitride, a metal nitride, etc. The metal of the metal nitride may include, e.g., aluminum (Al), zirconium (Zr), titanium (Ti), hafnium (Hf), etc.

A second insulating interlayer 430 covering the capacitors 420 may be formed in the first and second regions I and II to manufacture the semiconductor device.

As described above, the second conductive layer pattern 260 may be formed in the recess 250 formed by partially removing the upper portion of the substrate 100. The third conductive layer 270 may be formed on the first and second conductive layer patterns 205 and 260. The third conductive layer 270 and the second conductive layer pattern 260 may be sequentially patterned to form the bit line contact 262 and the bit line structure 320. Accordingly, the recess 250 may be formed to have a reduced aspect ratio. Even though a sidewall of the recess 250 may have a higher slope, no void may be formed in the second conductive layer pattern 260. Therefore, etching defects may not be generated during the patterning process for formation of the bit line contact 262 and the bit line structure 320, and thus the misalignment of the bit line contact 262 and the bit line structure 320 may be prevented.

Moreover, the third conductive layer 270 may cover the top surface of the second conductive layer pattern 260. Thus, even if a void were to be formed in the second conductive layer pattern 260, the third conductive layer pattern 272 would cover and/or fill the void. When the barrier layer 280 is formed, a material, e.g., a metal, a metal nitride and/or a metal oxide, etc., of the barrier layer 280 would not be introduced into the void.

By way of summation and review, in forming a highly integrated semiconductor device, a gate structure may be formed in a substrate to form a buried channel array transistor (BCAT). In this case, a recess may be formed at an upper portion of the substrate, a conductive layer may be formed to fill the recess, a barrier layer and a metal layer may be sequentially formed on the conductive layer, and the metal layer, the barrier layer and the conductive layer may be patterned using a hard mask as an etching mask to form a bit line contact and a bit line structure electrically connected to the BCAT. However, a void may be formed in the conductive layer filling the recess due to a high aspect ratio of the recess. Thus, the metal layer, the barrier layer and the conductive layer may not be etched properly during the patterning process, and impurities may be introduced into the conductive layer through the void.

Embodiments provide a method of manufacturing a semiconductor device having no undesired void therein. According to embodiments, a lower conductive layer pattern filling a recess at an upper portion of a substrate may be formed, an upper conductive layer may be formed on the lower conductive layer pattern, and the upper conductive layer and the lower conductive layer pattern may be patterned to form a bit line contact and a bit line structure. Accordingly, the recess may be formed to have a reduced aspect ratio, and even though a sidewall of the recess may have a high slope, no void may be formed in the lower conductive layer pattern. As a result, etching defects may not be generated during the patterning process for formation of the bit line contact and the bit line structure, and thus the misalignment of the bit line contact and the bit line structure may be prevented.

Moreover, even if a void were to be formed in the lower conductive layer pattern, the upper conductive layer would cover and/or fill the void. Thus, an additional process for filling and/or removing the void is not performed before a barrier layer is formed for formation of the bit line structure, and materials of the barrier layer are not introduced into the void. A deterioration of electrical characteristics of the semiconductor device due to a void may be prevented.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope thereof as set forth in the following claims.

What is claimed is:

1. A method of manufacturing a semiconductor device, the method comprising:
forming a first conductive layer on a substrate;
partially removing the first conductive layer and an upper portion of the substrate to form a recess;
forming a second conductive layer pattern to fill the recess;
forming a third conductive layer on the second conductive layer pattern and the first conductive layer; and
patterning the third conductive layer and the second conductive layer pattern to form a bit line structure and a bit line contact, respectively.

2. The method as claimed in claim 1, wherein the third conductive layer is formed to have a greater thickness than the first conductive layer.

3. The method as claimed in claim 1, further comprising, prior to forming the bit line structure and the bit line contact, sequentially forming a barrier layer, a metal layer and a mask on the third conductive layer.

4. The method as claimed in claim 3, wherein forming the bit line structure and the bit line contact includes etching the metal layer, the barrier layer, the third conductive layer and the second conductive layer pattern using the mask as an etching mask.

5. The method as claimed in claim 3, wherein:
the second conductive layer pattern and the third conductive layer are formed to include polysilicon doped with impurities, and
the barrier layer is formed to include a metal nitride.

6. The method as claimed in claim 1, wherein:
the second conductive layer pattern includes a plurality of second conductive layer patterns formed to be spaced apart from each other, and
the bit line contact includes a plurality of bit line contacts formed to be spaced apart from each other.

7. The method as claimed in claim 1, wherein the bit line structure is formed to extend in a first direction parallel to a top surface of the substrate.

8. The method as claimed in claim 1, further comprising, prior to forming the first conductive layer, forming a first gate structure in the substrate.

9. The method as claimed in claim 8, wherein forming the first gate structure in the substrate includes:
forming a trench at the upper portion of the substrate;
forming a first gate insulation layer on an inner wall of the trench;
forming a first gate electrode on the first gate insulation layer to partially fill the trench; and
forming a capping layer pattern on the first gate electrode to fill a remaining portion of the trench.

10. The method as claimed in claim 8, wherein:
the bit line structure is formed to extend in a first direction parallel to a top surface of the substrate, and
the first gate structure is formed to extend in a second direction parallel to the top surface of the substrate and perpendicular to the first direction.

11. The method as claimed in claim 1, further comprising, after forming the bit line structure and the bit line contact:
forming an etch stop layer pattern on the substrate to surround the bit line structure and the bit line contact;
forming an insulating interlayer on the etch stop layer pattern;
partially removing the insulating interlayer and the etch stop layer pattern to form an opening exposing a top surface of the substrate; and
forming a capacitor contact to fill the opening.

12. The method as claimed in claim 11, further comprising, after forming the capacitor contact, forming a capacitor to contact the capacitor contact.

13. The method as claimed in claim 1, wherein:
the substrate includes a cell region in which memory cells are formed, and a peripheral region in which peripheral circuits are formed,
the method further includes, prior to forming the first conductive layer, forming a pad layer and a second gate insulation layer on the cell region and the peripheral region, respectively, and
the first conductive layer is formed on the pad layer and the second gate insulation layer.

14. The method as claimed in claim 13, wherein the first conductive layer is formed to include polysilicon doped with impurities.

15. The method as claimed in claim 13, further comprising, prior to forming the bit line structure and the bit line contact, forming a barrier layer, a metal layer and a mask on the third conductive layer sequentially,
wherein forming the bit line structure and the bit line contact includes etching the metal layer, the barrier layer, the third conductive layer and the second conductive layer pattern using the mask as an etching mask to form the bit line structure and the bit line contact in the cell region, the method further including etching the metal layer, the barrier layer, the third conductive layer, the first conductive layer and the second gate insulation layer to form a second gate structure in the peripheral region.

16. A method of manufacturing a semiconductor device, the method comprising:
providing a substrate having a buried channel array transistor including a first gate structure formed therein, the substrate including an active region and a field region;
forming a pad layer, an etch stop layer and a first conductive layer on the substrate;
partially removing the pad layer, the etch stop layer, and the first conductive layer and an upper portion of the substrate to foam a pad layer pattern, an etch stop layer pattern and a first conductive layer pattern and to form recesses spaced apart from each other in a first direction and a second direction;
forming a second conductive layer pattern to fill the recesses, the second conductive layer pattern having a top surface substantially coplanar with a top surface of the first conductive pattern;
forming a third conductive layer, a barrier layer, a metal layer, and a mask on the second conductive layer pattern and the first conductive layer pattern; and
patterning the metal layer, the barrier layer and the third conductive layer using the mask to form a metal layer pattern, a barrier layer pattern, and a third conductive layer pattern constituting bit line structures and further patterning the second conductive layer pattern to form bit line contacts in the recesses, the bit line contacts contacting the substrate in the active region.

17. The method of claim 16, wherein the second conductive layer pattern and the third conductive layer pattern are formed of a same conductive material such that the third conductive layer pattern merges with the bit line contacts.

18. The method of claim 17, wherein the second conductive layer pattern and the third conductive layer pattern each include polysilicon doped with impurities.

19. The method of claim 16, wherein the bit line structures extend in the first direction parallel to the substrate.

20. The method of claim 19, further including forming a capacitor contact between two of the bit line structures and forming a capacitor electrically connected to the capacitor contact.
